(19) United States
(12) Patent Application Publication
(10) Pub. No.: US 2007/0275650 A1
(43) Pub. Date: Nov. 29, 2007

(54) Quiescent computer casing

(75) Inventor: Deng-Hsi Chen, Liu-Tu Industrial Park (TW)

Correspondence Address: TROXELL LAW OFFICE PLLC, SUITE 1404, 5205 LEESBURG PIKE, FALLS CHURCH, VA, 22041, US

(73) Assignee: Lian Li Industrial Co., Ltd.

(21) Appl. No.: 11/432,615

(22) Filed: May 12, 2006

(51) Int. Cl. H01L 23/467; H05K 5/00

(52) U.S. Cl. 454/184; 165/121

(57) ABSTRACT

In a quiescent computer casing, two sides of an inner rack of the casing are enclosed by inner side panels, so as to form interlining structures between the inner side panels and external side panels. By using cooling fans of an air entrance rack in a front of the inner rack, cold air will be sucked in from air entrance holes on the external side panels through air entrance openings at two sides of the air entrance rack and the interlinings between the inner and external side panels. A soundproof hood with a dual-division is installed at a rear side of the casing for blocking the air to enter and to exit, so as to reduce noises generated when the air enters into and exits the cooling fans and generated by interior parts of the casing to a minimum.

### BACKGROUND OF THE INVENTION

(a) Field of the Invention

The present invention relates to a quiescent computer casing, and more particularly to a computer casing structure which can greatly improve a soundproof effect without affecting its effect of heat dissipation.

(b) Description of the Prior Art

A current desktop computer is composed of a host, a monitor, and input/output equipment, wherein the host is a casing made of metallic panels, and an interior of which is installed with all kinds of electronic parts (such as a central processing unit, a memory, a motherboard, disk drives, and all kinds of interface cards). In addition to being able to protect the interior electronic parts, the casing is also provided with a function to prevent an electromagnetic wave from leaking out. For an ordinary user, a beauty of shape is necessary, for a player who loves to DIY (Do-It-Yourself), a convenience in disassembling is also required, and for a user who needs to expand the equipment frequently, an enough space and an effect of heat dissipation are definitely indispensable.

As the effect of heat dissipation is one of the important factors for the computer casing, therefore cooling fans are used for all of the existing computer casings to expel heat generated from the interior electronic parts. Referring to FIG. 1, it shows a configuration of an interior space of a most of the computer casings. Four panels a1 at a front, rear, top, and bottom sides are assembled into a flat rectangular body, a position close to a rear side of front panel a1 is provided with an emplacement rack b for installing the disk drives, and an upper position close to a back panel a1 is provided with a support rack c for installing a power supply. The support rack c will usually be extended forward to the front panel a1 to enhance its strength. After all of the electronic parts are installed in an interior of a casing a, most of its area will be occupied by a motherboard d on which a central processing unit d1, a memory d2, and interface cards d3 are required to be installed. In addition, even signal lines of the disk drives should be connected to proper slots on the motherboard. As the disk drives will be installed in an about stack type, cooling fans e will usually be installed on the front panel a1, the back panel a1, or two side panels. These cooling fans e are mostly connected to an ambient environment to expel out the heat for achieving an object of dissipating the heat. However, as the cooling fans e are directly connected to the ambient environment, noises generated by the cooling fans e will be directly transmitted to an exterior of casing a, which will usually enable the user to be very troublesome for the heat dissipation effect and the noises, thereby definitely requiring an improvement.

Accordingly, in view of the shortcomings of noises generated in dissipating the heat while using the ordinary computer, a brand new quiescent computer casing is invented, wherein interlining structures formed by inner and exterior side panels and a design of soundproof hood at an air accessing position at a rear side are used to form an air entrance and outlet ducts required by the cooling fans, such that all of the air entrance and outlet ducts can sufficiently reduce the noises generated by the cooling fans, due to that an air entrance opening is not facing to an air outlet opening. Furthermore, a soundproof material is affixed at proper positions in interior faces of casing and the two-layer side panels, which will also reduce the noises generated by the interior parts.

### SUMMARY OF THE INVENTION

The primary object of present invention is to provide a quiescent computer casing which can reduce noises generated by cooling fans and interior parts without affecting its original effect of heat dissipation.

Accordingly, the quiescent computer casing of present invention comprises primarily a casing and two external side panels which are provided with air entrance holes, wherein an interior of the casing is provided with an inner rack, two sides of which are enclosed by inner side panels, respectively; the external side panels are installed at openings at two sides of the casing; and the inner rack is separated with the openings at two sides of the casing by a proper distance, such that interlining structures are formed between the inner side panels and the external side panels. An air entrance rack is installed on the inner rack, at a position close to a front side of the casing, two sides of the air entrance rack are provided with a plurality of air suction openings, a rear side of the air entrance rack is provided with a plurality of cooling fans, and a proper shockproof material is located at connection places between the cooling fans and the air entrance rack. On the other hand, a rear side of the air entrance rack is installed with a hard disk rack which is provided with a plurality of stack-type fast assembling slots, and each grid of slots is installed with a heat sink of hard disk. Each heat sink of hard disk is in a U-shape from a side view, its side-width is corresponding to a width of the hard disk, and a top side of the heat sink is parallel installed with a plurality of cooling fins. An air outlet rack is installed on an inner surface of air outlet opening aligning with a rear side of the casing, and is provided with a plurality of cooling fans. A lower rear side of the casing is installed with a cooling fan, and a front of which is vertically installed with a CPU (Central Processing Unit) cooling hood having an orientation being able to be adjusted according to a position of CPU. A soundproof hood is installed at a rear side of the casing, and is divided into an air outlet zone and an air entrance zone, wherein the air outlet zone is corresponding to a size of air outlet opening and a power supply at a rear side of the casing, and the air entrance zone is corresponding to a size of CPU cooling hood and cooling fan. In addition, connection places between the inner side panels and the inner rack, between the cooling fans and the casing, as well as between the cooling fans and the air outlet rack are all provided with a proper shockproof material.

According to the aforementioned structures, when the computer is turned on and being used, the cooling fans inside the casing will be operating accordingly. In the same time, the cooling fans at the air entrance rack will generate an inward suction force to enable outside cold air to pass through the air entrance holes on the external side panels, through the interlining structures between the inner and external side panels, and then enter into the casing through the air suction openings at two sides of the air entrance rack. In addition, the air entrance holes on the external side panels are not facing to the air suction openings on the air entrance rack, and the more distant between then, the lesser noises from sucking the air will be generated. On the other hand, the air is directly entering into the cooling fan of CPU cooling hood from the air entrance zone at the soundproof hood at the rear side of casing. Therefore, two different air entrance ducts will be formed and hot air inside the ducts will be accumulated and then expelled out of the air outlet zone of soundproof hood at the rear side of casing, by using the cooling fans on the air outlet rack and a fan inside the power supply. As the air entrance and outlet ducts are subjected to a proper blocking, the noises which are generated, when the air is entering into and exiting the casing, will be reduced to a minimum. Furthermore, as the casing is formed into a multi-layer style, and the proper shockproof material are located at all of the connection places between the inner side panels and the inner rack, between the cooling fans and the casing, as well as between the cooling fans and the air outlet rack, vibrations and noises generated by the interior parts and cooling fans can be also effectively reduced. On the other hand, to maintain a certain effect of heat dissipation, the CPU cooling hood for assisting the cooling is installed on a heat-generating element—CPU—inside the computer host, which can quickly suck in the cold air outside of the casing and directly blow it onto a CPU heat sink. The other primary heat-generating element—hard disk—is installed on a hard disk rack. As the hard disk rack is installed at the rear side of air entrance rack, and each hard disk is provided with its corresponding heat sink which can be used to quickly accumulate the heat on the hard disk surface onto the heat sink, and to directly expel the heat with the cold air which is directly sucked in by the cooling fans of air entrance rack. Finally, the hot air with heat is expelled out after being integrally accumulated by the cooling fans on the air outlet rack and the fan inside the power supply, thereby maintaining a good effect of heat dissipation.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a schematic view of a structure of a conventional computer casing.

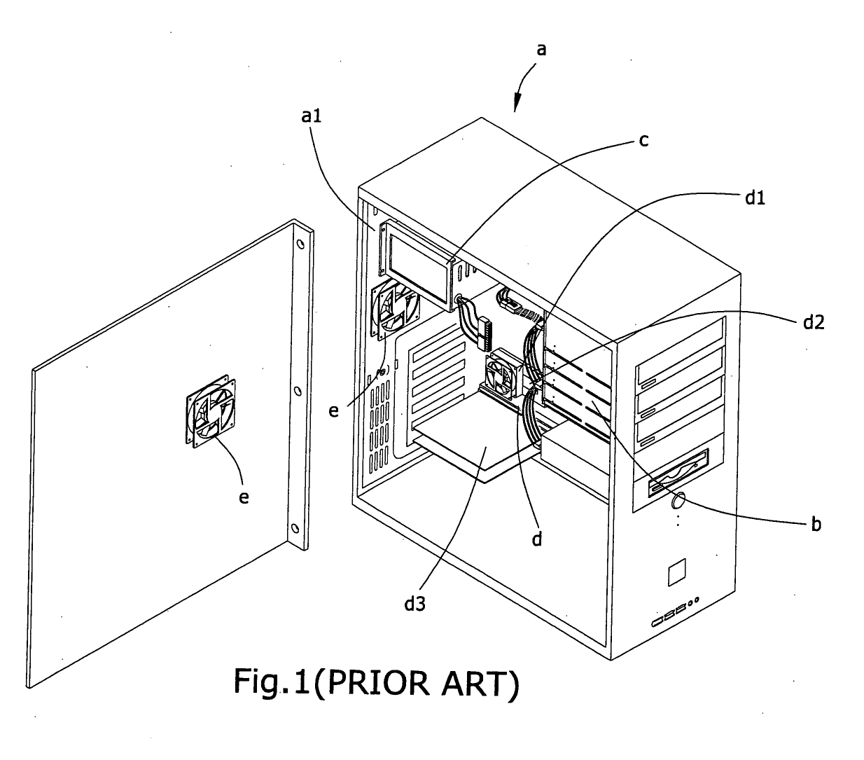

FIG. 2 shows an exploded view of the present invention.

FIG. 3 shows a cutaway view of the present invention after being assembled.

FIG. 4 shows an exploded view of a soundproof hood of the present invention.

FIG. 5 shows a schematic view of a structure of a panel in another embodiment of the present invention.

FIG. 6 shows a schematic view of a structure of a panel cover in another embodiment of the present invention.

FIG. 7 shows a schematic view of air flow upon using the present invention.

FIG. 8 shows another schematic view of air flow upon using the present invention.

### DETAILED DESCRIPTION OF THE PREFERRED EMBODIMENTS

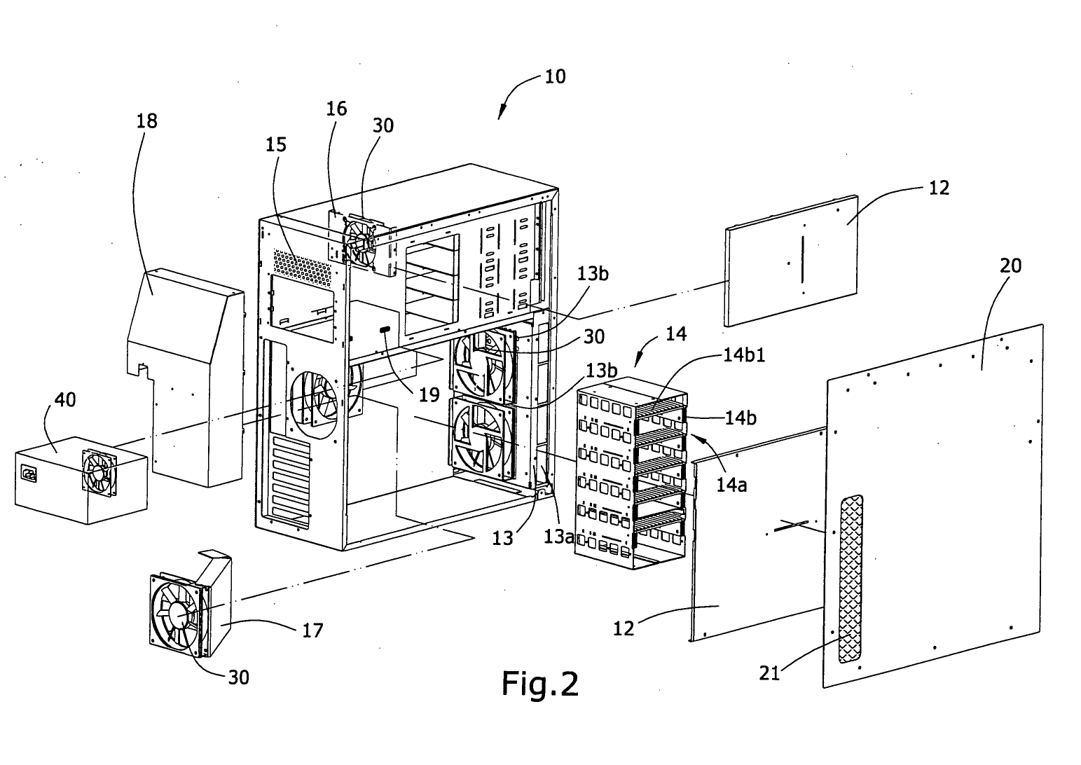

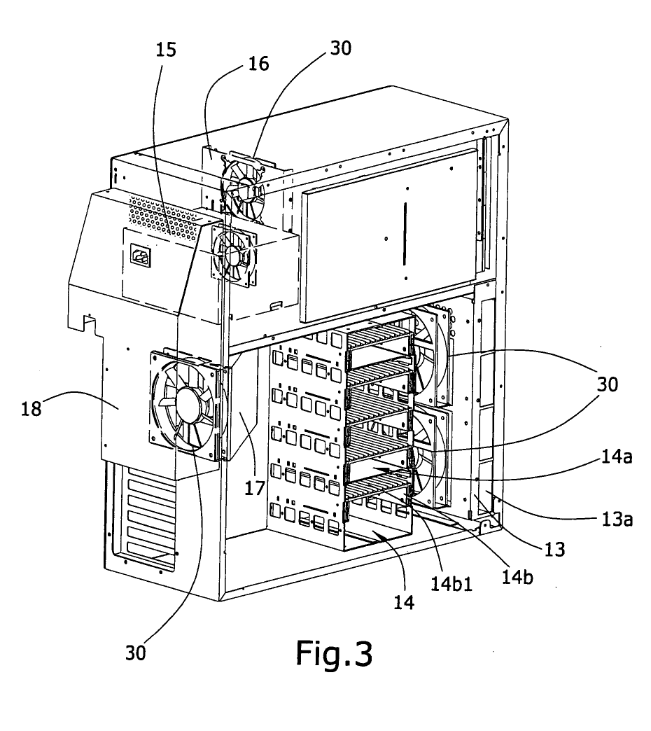

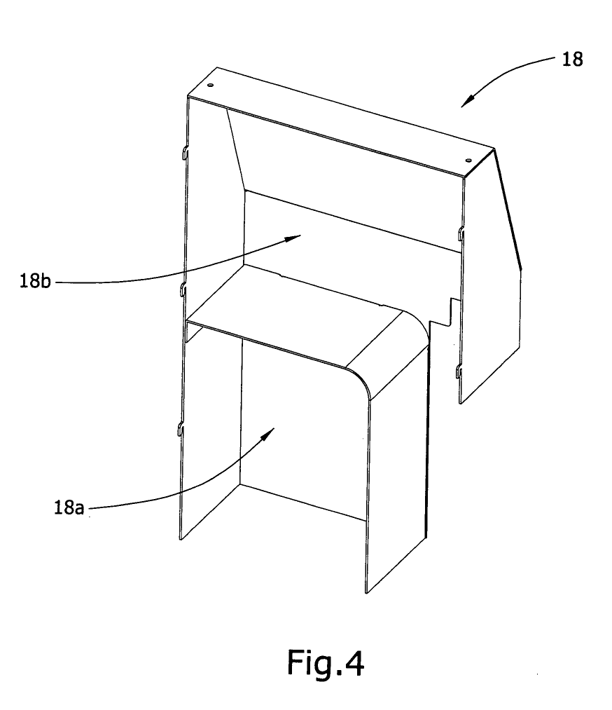

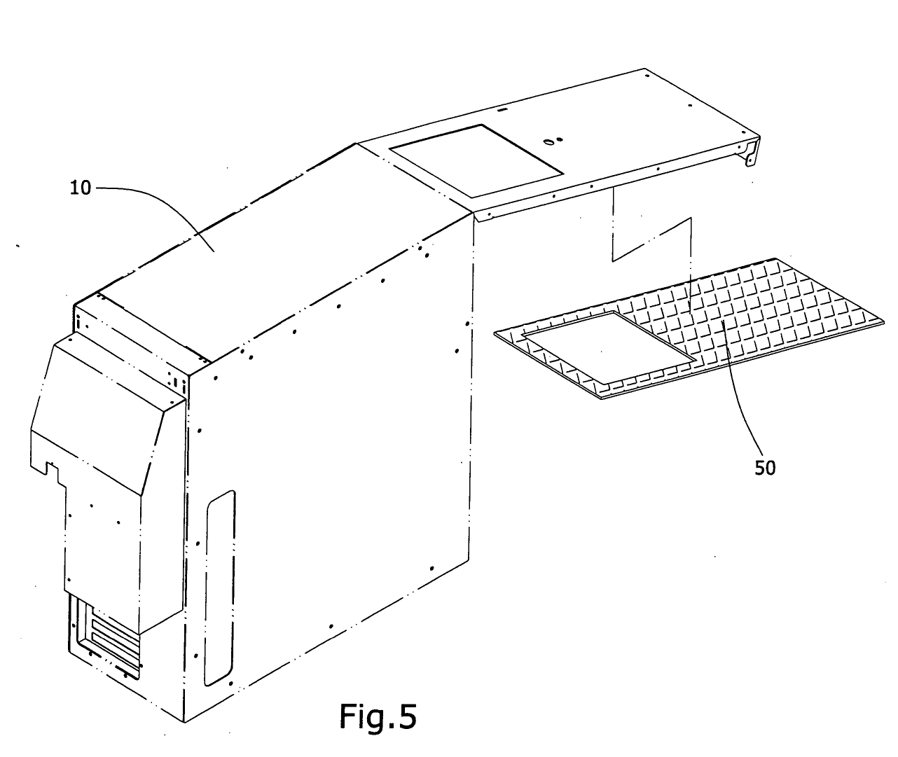

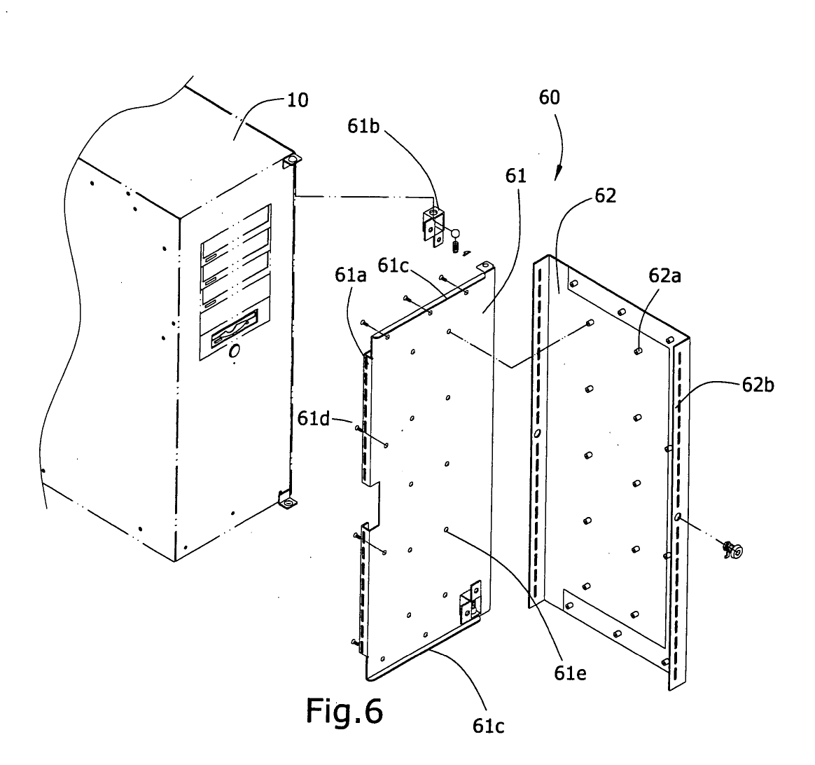

Referring to FIGS. 2 to 4, a quiescent computer casing of the present invention comprises primarily a casing 10, and two external side panels 20, wherein an interior of the casing is provided with an inner rack 11, and two sides of which are enclosed by inner side panels 12 respectively; the external side panels 20 are installed at openings of two sides of the casing 10; and the inner rack 11 is separated with the openings at two sides of the casing 10 by a proper distance, so as to form interlining structures between the inner side panels 12 and the external side panels 20. An air entrance rack 13 is installed on the inner rack 11, at a position close to a front side of the casing 10 with two sides of the air entrance rack 13 being provided with a plurality of air suction openings 13a respectively, and a rear side of the air entrance rack 13 is installed with a plurality of cooling fans 30. Connection places between the cooling fans 30 and the air entrance rack 13 are provided with a proper shockproof material 13b, and a rear side of the air entrance rack 13 is installed with a hard disk rack 14 which is provided with a plurality of stack-type fast assembling slots 14 with each grid of slots 14 being installed with a heat sink 14b. Each heat sink 14b is in a U-shape from a side view, its side-width is corresponding to a width of hard disk, and its top side is parallel provided with cooling fins 14b1. An inner surface of an air outlet opening 15 aligned with a rear side of the casing 10 is provided with an air outlet rack 16 on which is installed with cooling fans 30. A rear lower side of the casing 10 is also provided with a cooling fan 30, a front side of which is vertically installed with a CPU cooling hood 17 with its orientation being able to be adjusted according to a position of CPU. A rear side of the casing 10 is provided with a soundproof hood 18 which is divided into an air entrance zone 18a and an air outlet zone 18b, wherein the air outlet zone 18b is corresponding to a size of the air outlet opening 15 and a power supply 40 at the rear side of the casing 10, and the air entrance zone 18a is corresponding to a size of the CPU cooling hood 17 and cooling fan 30. In addition, connection places between the inner side panels 12 and the inner rack 11, between the cooling fans 30 and the casing 10, as well as between the cooling fans 30 and the air outlet rack 13 are all provided with a proper shockproof material 19. Moreover, referring to FIG. 5, to enhance a soundproof capability at a front side of the casing 10, an inner surface of a front panel of the casing 10 is provided with a proper soundproof material 50 (which is an ordinary foaming material or a soundproof and shockproof cushion). Referring to FIG. 6, a panel cover 60 can be also located in a front of the front panel of casing 10. This kind of panel cover 60 includes a base panel 61 and at least one decoration panel 62, wherein two sides of the base panel 61 are bended inward to form spacer pieces 61a and pivot plates 61b, and an upper and lower edge of the base panel 61 are bended toward the front side to form sealing plates 61c. The spacer pieces 61a at two sides of the base panel 61 are provided with collision-proof rubbers 61d, and proper positions on the base panel 61 are formed with a plurality of fixing holes 61e. On the other hand, the decoration panel 62 can be a single piece or can be assembled with a plurality of pieces, a plurality of pins 62a is located on its inner surface, at positions corresponding to the base panel 61, and two sides of it are provided with bending plates 62b to enclose the spacer pieces 61a of the base panel 61, thereby assembling the decoration panel 62 with the base panel 61 to form a two-layer design.

Proper positions on the two external side panels 20 are provided with long-shape air entrance holes 21 which are not facing to the air suction openings 13a of the air entrance rack 13, and the more distant between them, the lesser the noise will be generated.

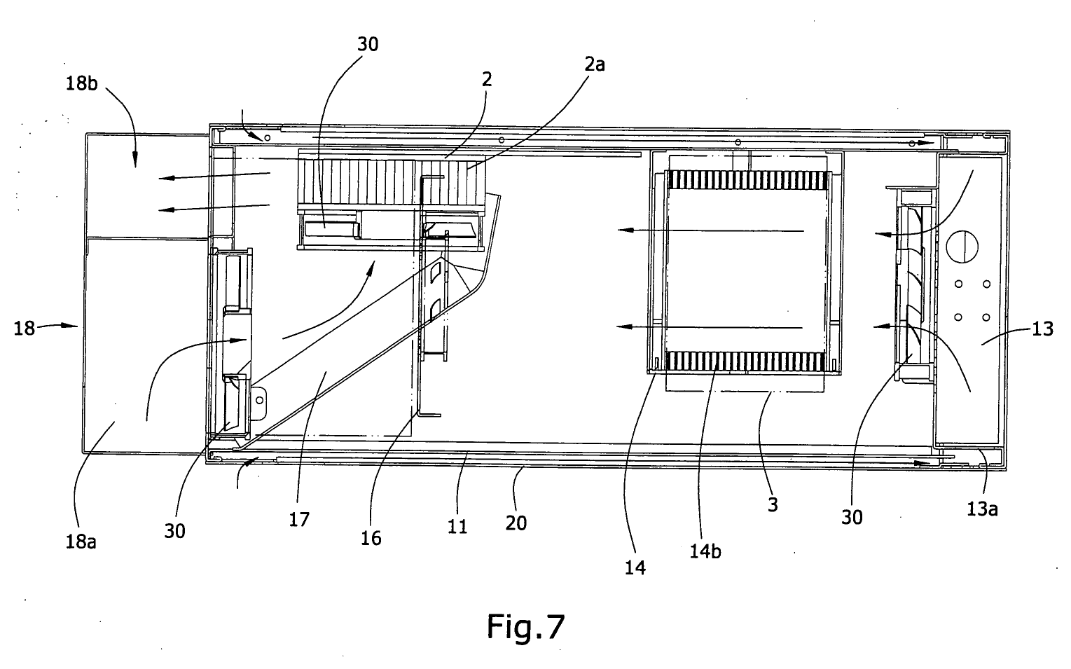

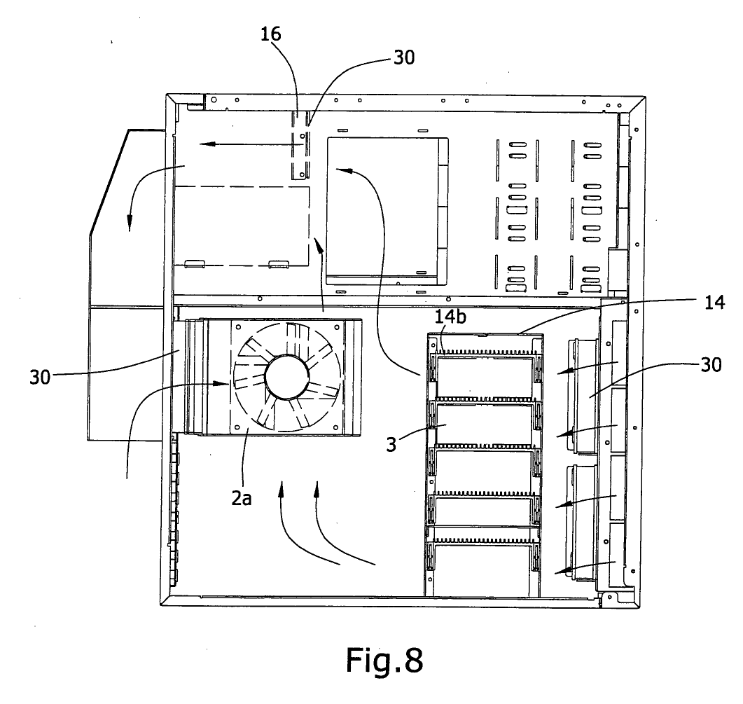

Referring to FIG. 7 and FIG. 8, in a same time of operating the computer, the cooling fans 30 at the air entrance rack 13 will generate an inward suction force, allowing outside cold air to pass through the air entrance holes 21 of the external side panels 20, through the interlining structures between the inner and external side panels 11, 20, and enter into the casing 10 through the air suction openings 13a at two sides of the air entrance rack 13. On the other hand, the air is directly entering into the cooling fan 30 of CPU cooling hood 17 from the air entrance zone 18a of soundproof hood 18 at the rear side of casing 10, thereby forming two different air entrance ducts. Hot air in an interior of the casing 10 is accumulated and then expelled integrally from the air outlet zone 18b of soundproof hood 18 at the rear side of casing 10 by using the cooling fans 30 on the air outlet rack 17 and a fan inside the power supply 40. On the other hand, to maintain a certain effect of heat dissipation, the CPU cooling hood 17 is installed on a heat-generating element—CPU 2—inside the computer host to assist in cooling the CPU. The CPU cooling hood 17 can quickly suck in the cold air outside of the casing 10, and directly blow it onto a heat sink 2a of CPU 2. The other primary heat-generating element—hard disk—is installed on the hard disk rack 14. As the hard disk rack 14 is locate at a rear side of the air entrance rack 13, and each hard disk 3 is provided with its corresponding heat sink 14b to quickly accumulate heat on the surface of hard disk 3 onto the heat sink 14b, and to directly expel out the heat with the cold air which is directly sucked in by the cooling fans 30 of air entrance rack 13.

Accordingly, the quiescent computer casing of present invention uses the interlining structures formed by the inner and external side panels and the soundproof hood at the rear side of casing to effectively block the noises generated when the air is entering into and exiting the casing, and is provided with a structure which will not affect an original effect of heat dissipation.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A quiescent computer casing including a casing and two external side panels which are provided with air entrance holes, wherein an interior of the casing is provided with an inner rack, and two sides of which are enclosed by inner side panels respectively, for forming interlining structures between the inner side panels and external side panels; an air entrance rack being located on the inner rack, at a position close to a front side of the casing, two sides of the air entrance rack being provided with air entrance openings respectively, an inner surface at a rear side of the casing being provided with an air outlet rack and a CPU (Central Processing Unit) cooling hood, and proper positions of the air entrance rack, the air outlet rack, the CPU cooling hood all being provided with cooling fans respectively, and a rear side of the casing being provided with a soundproof hood.

2. The quiescent computer casing according to claim 1, wherein a proper distance is left between the inner rack and the openings at two sides of the casing, thereby forming the interlining structures between the inner side panels and the external side panels.

3. The quiescent computer casing according to claim 1, wherein a rear side of the air entrance rack is provided with a plurality of cooling fans, and connection places between the cooling fans and the air entrance rack are provided with a proper shockproof material.

4. The quiescent computer casing according to claim 1, wherein a rear side of the air entrance rack is installed with a hard disk rack which is provided with a plurality of stack-type fast assembling slots, with each grid of slots being provided with a heat sink; each heat sink of hard disk being in a U-shape from a side view, its side-width being corresponding to a width of hard disk, and its top side being parallel provided with cooling fins.

5. The quiescent computer casing according to claim 1, wherein the air outlet rack is aligned with an air outlet opening at a rear side of the casing, and the air outlet rack is provided with cooling fans.

6. The quiescent computer casing according to claim 1, wherein the CPU cooling hood is installed at a rear lower position of the casing, is vertically installed in a front of cooling fan, and is having an orientation which can be adjusted according to a position of CPU.

7. The quiescent computer casing according to claim 1, wherein the soundproof hood is divided into an air entrance zone and an air outlet zone, with the air outlet zone being corresponding to a size of the air outlet opening and a power supply at a rear side of the casing, and the air entrance zone being corresponding to a size of the CPU cooling hood and cooling fan.

8. The quiescent computer casing according to claim 1, wherein connection places between the inner side panels and the inner rack are all provided with a proper shockproof material.

9. The quiescent computer casing according to claim 1, wherein connection places between the cooling fans and the casing are all provided with a proper shockproof material.

10. The quiescent computer casing according to claim 1, wherein connection places between the cooling fans and the air outlet rack are all provided with a proper shockproof material.

11. The quiescent computer casing according to claim 1, wherein an inner surface of a front panel of the casing is provided with a proper soundproof material.

12. The quiescent computer casing according to claim 11, wherein the soundproof material is an ordinary foaming material.

13. The quiescent computer casing according to claim 11, wherein the soundproof material is an ordinary soundproof and shockproof cushion.

14. The quiescent computer casing according to claim 1, wherein a panel cover is located in a front of front panel of the casing and is provided with a base panel and at least one decoration panel; two sides of the base panel being bended toward the inner side to form spacer pieces and pivot plates, and an upper and lower edge of the base panel being bended toward the front side to form sealing plates; the spacer pieces at two sides of the base panel being provided with collision-proof rubbers, and proper positions on the base panel being provided with a plurality of fixing holes; a plurality of pins being located at an inner surface of the decoration panel, at positions corresponding to the base panel, two sides of the decoration panel being provided with bending plates to enclose the spacer pieces of base panel, thereby assembling the decoration panel with the base panel to form a two-layer design.
